(19) United States
(12) Patent Application Publication
(10) Pub. No.: US 2017/0084784 A1
(43) Pub. Date: Mar. 23, 2017

(54) LIGHT-EMITTING DEVICE AND PRODUCTION METHOD THEREFOR

(71) Applicant: TOYODA GOSEI CO., LTD., Kiyosu-shi (JP)

(72) Inventors: Koichi GOSHONOO, Kiyosu-shi (JP); Shingo TOTANI, Kiyosu-shi (JP)

(21) Appl. No.: 15/253,558

(22) Filed: Aug. 31, 2016

(30) Foreign Application Priority Data
Sep. 18, 2015 (JP) 2015-185220

(51) Int. Cl. H01L 33/14; H01L 33/04; H01L 33/46; H01L 33/00; H01L 33/32; H01L 33/42

(52) U.S. Cl. CPC H01L 33/145; H01L 33/32; H01L 33/42; H01L 33/46; H01L 33/0075; H01L 33/04

(57) ABSTRACT

The light-emitting device of the present technique includes a substrate, a Group III nitride semiconductor layer disposed on the substrate, a current-blocking layer disposed on the Group III nitride semiconductor layer, a transparent conductive oxide film disposed on the Group III nitride semiconductor layer and the current-blocking layer, a dielectric film covering the Group III nitride semiconductor layer and at least a part of the transparent conductive oxide film, and a phosphor-containing resin coating disposed on the dielectric film. The Group III nitride semiconductor layer has a refractive index greater than that of the transparent conductive oxide film. The transparent conductive oxide film has a refractive index greater than that of the dielectric film. The dielectric film has a refractive index greater than that of the phosphor-containing resin coating. The current-blocking layer has a refractive index smaller than that of the phosphor-containing resin coating.

### BACKGROUND OF THE INVENTION

Field of the Invention

The present technique relates to a light-emitting device and to a method for producing the device.

Background Art

Generally, a Group III nitride semiconductor light-emitting device has a light-emitting layer which emits light through recombination of electrons and holes, an n-type semiconductor layer, and a p-type semiconductor layer. However, the light generated in the light-emitting layer is not completely extracted from the Group III nitride semiconductor light-emitting device to the outside. The light is partially absorbed by members of the Group III nitride semiconductor light-emitting device, or reflected by members of the Group III nitride semiconductor light-emitting device.

In order to solve the problem, some techniques have been developed for suitably extracting light from Group III nitride semiconductor light-emitting devices. Among them, Patent Document 1 discloses a technique of forming a transparent high-refractive-index film 15 (TiO₂) on ITO (refractive index: about 1.9) (see, for example, FIG. 6 of Patent Document 1). In the transparent high-refractive-index film 15, the refractive index in the film gradually decreases from the ITO side toward the light extraction side (see paragraph [0060] and FIG. 6 of Patent Document 1), whereby light extraction from the light-emitting layer can be facilitated.

Patent Document 1: Japanese Patent Application Laid-Open (kokai) No. 2013-84739

As described above, even though the efficiency of light extraction from a semiconductor light-emitting element has been successfully enhanced, the light emitted from the semiconductor light-emitting element may be reflected by a phosphor-containing resin coating, when the light enters the phosphor-containing resin coating. Also, when the light enters an electrode, the light is absorbed by the electrode to a certain extent. Thus, the conventionally developed light-emitting devices exhibit reduced light extraction efficiency.

### SUMMARY OF THE INVENTION

The present technique has been conceived in order to solve the aforementioned problems involved in conventional techniques. Thus, an object of the present technique is to provide a light-emitting device which realizes suppression of light absorption by electrodes as well as easy light extraction. Another object is to provide a production method therefor.

In a first aspect of the present technique, there is provided a light-emitting device, comprising: a substrate, a Group III nitride semiconductor layer disposed on the substrate, a current-blocking layer disposed on the Group III nitride semiconductor layer, a transparent conductive oxide film disposed on the Group III nitride semiconductor layer and the current-blocking layer, a first dielectric film covering at least a part of the Group III nitride semiconductor layer and at least a part of the transparent conductive oxide film, and a phosphor-containing resin coating disposed on the first dielectric film. The Group III nitride semiconductor layer has a refractive index greater than that of the transparent conductive oxide film. The transparent conductive oxide film has a refractive index greater than that of the first dielectric film. The first dielectric film has a refractive index greater than that of the phosphor-containing resin coating. The current-blocking layer has a refractive index smaller than that of the phosphor-containing resin coating.

In the light-emitting device, the refractive index decreases in the direction from the Group III nitride semiconductor layer, the transparent conductive oxide film, the first dielectric film, and the phosphor-containing resin coating. The light emitted by the light-emitting layer passes sequentially through the Group III nitride semiconductor layer, the transparent conductive oxide film, the first dielectric film, and the phosphor-containing resin coating. Thus, the light emitted by the light-emitting device can be extracted to the outside, with total reflection being prevented to a certain extent. Also, the refractive index of the current-blocking layer is smaller than that of the phosphor-containing resin coating. Thus, the light which is emitted by the Group III nitride semiconductor layer and enters the transparent conductive oxide film via the current-blocking layer tends to be reflected by the interface between the current-blocking layer and the transparent conductive oxide film. Accordingly, the light passing through the route to the outside is not likely to be reflected inside the light-emitting device, while the light moving toward electrodes is readily reflected inside the light-emitting device. Therefore, the emitted light is not completely absorbed by the electrodes and can be extracted to the outside. As a result, the light-emitting device of the present technique exhibits excellent light extraction efficiency.

In a second aspect of the present technique, the light-emitting device includes a reflective film disposed on the transparent conductive oxide film, and a second dielectric film covering the reflective film. Also, the second dielectric film has a refractive index smaller than that of the phosphor-containing resin coating.

In a third aspect of the present technique, the first dielectric film covers a side surface of the substrate. The substrate has a refractive index greater than that of the first dielectric film.

In a fourth aspect of the present technique, the light-emitting device has an emission wavelength of 400 nm to 800 nm.

In a fifth aspect of the present technique, the transparent conductive oxide film is formed of IZO.

In a sixth aspect of the present technique, there is provided a method for producing a light-emitting device, the method comprising: a semiconductor layer formation step of forming a Group III nitride semiconductor layer on a substrate, a current-blocking layer formation step of forming a current-blocking layer on the Group III nitride semiconductor layer, a transparent conductive oxide film formation step of forming a transparent conductive oxide film on the Group III nitride semiconductor layer and the current-blocking layer, a first dielectric film formation step of covering at least a part of the Group III nitride semiconductor layer and at least a part of the transparent conductive oxide film with a first dielectric film, and a phosphor-containing resin coating formation step forming a phosphor-containing resin coating on the first dielectric film. The Group III nitride semiconductor layer has a refractive index greater than that of the transparent conductive oxide film. The transparent conductive oxide film has a refractive index greater than that of the first dielectric film. The first dielectric film has a refractive index greater than that of the phosphor-containing resin coating. The current-blocking layer has a refractive index smaller than that of the phosphor-containing resin coating.

In a seventh aspect of the present technique, the light-emitting device production method includes a reflective film formation step of forming a reflective film on the transparent conductive oxide film, and a second dielectric film formation step of covering the reflective film with a second dielectric film. The second dielectric film has a refractive index smaller than that of the phosphor-containing resin coating.

In an eighth aspect of the present technique, the first dielectric film is formed on a side surface of the substrate. The substrate has a refractive index greater than that of the first dielectric film.

According to the light-emitting device of the present technique and the production method therefor, light absorption by electrodes can be suppressed, and light extraction to the outside can be facilitated.

### BRIEF DESCRIPTION OF THE DRAWINGS

Various other objects, features, and many of the attendant advantages of the present technique will be readily appreciated as the same becomes better understood with reference to the following detailed description of the preferred embodiments when considered in connection with the accompanying drawings, in which:

FIG. 1 is a plan view of the structure of a light-emitting device of a first embodiment;

FIG. 2 is a cross-section of FIG. 1, cut along II-II;

FIG. 3 is a representation showing the layer stacking configuration and the refractive indexes of respective layers;

FIG. 4 is a graph showing wavelength-refractive index relationships of materials;

FIG. 5 is a graph showing a relationship between the wavelength of the light emitted by the light-emitting device and the intensity of the light;

FIG. 6 is a schematic view of a stacking configuration employed in simulation;

FIG. 7 is a graph showing a relationship between the incident angle and the transmittance when the light wavelength is 450 nm;

FIG. 8 is a graph showing a relationship between the incident angle and the transmittance when the light wavelength is 570 nm;

FIG. 9 is a plan view of the structure of a light-emitting device according to a variation of the first embodiment;

FIG. 10 is a cross-section of FIG. 9, cut along X-X;

FIG. 11 is a plan view of the structure of a light-emitting device of a second embodiment;

FIG. 12 is a cross-section of FIG. 11, cut along XII-XII; and

FIG. 13 is a cross-section of the structure of a light-emitting device of a third embodiment.

### DETAILED DESCRIPTION OF PREFERRED EMBODIMENT

With reference to the drawings, specific embodiments of the semiconductor light-emitting device of the present technique and the production method therefor will next be described in detail. However, these embodiments should not be construed as limiting the technique thereto. The below-described stacking configuration of the layers of the semiconductor light-emitting device and the electrode structure are given only for the illustration purpose, and other stacking configurations differing therefrom may also be employed. The thickness of each of the layers shown in the drawings is not an actual value, but a conceptual value.

### First Embodiment

### 1. Light-Emitting Device

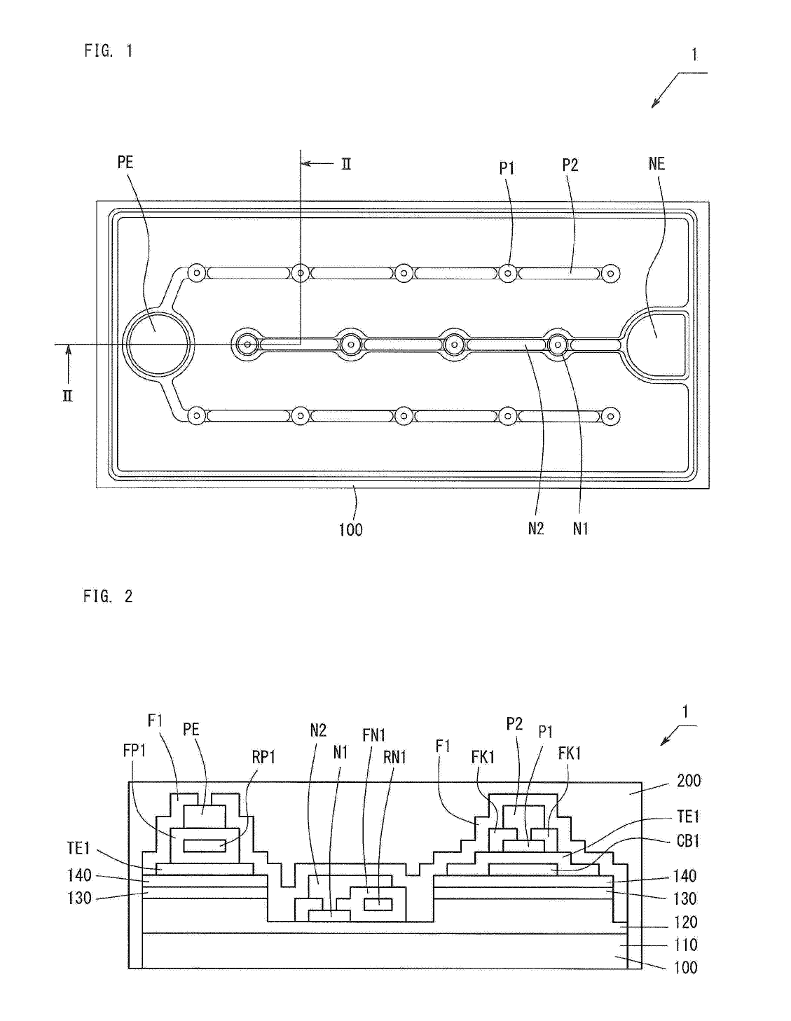

FIG. 1 is plan view showing the structure of a light-emitting device 1 according to the first embodiment. FIG. 2 is a cross-section of the light-emitting device 1 shown in FIG. 1, cut along II-II. The light-emitting device 1 has a light-emitting element 100 and a phosphor-containing resin coating 200. The light-emitting device 1 is a Group III nitride semiconductor light-emitting device which emits white light. The light-emitting device 1 provides light having a wavelength of 400 nm to 800 nm. The light-emitting element 100 is a semiconductor light-emitting device of face-up type having a plurality of semiconductor layers formed of a Group III nitride semiconductor.

As shown in FIGS. 1 and 2, the light-emitting element 100 has a substrate 110, an n-type semiconductor layer 120, a light-emitting layer 130, a p-type semiconductor layer 140, a current-blocking layer CB1, a transparent conductive oxide film TE1, a dielectric film F1, a dielectric film FN1, a dielectric film FP1, a dielectric film FK1, a reflective film RN1, a reflective film RP1, n-side dot electrodes N1, an n-side wiring electrode N2, an n-side pad electrode NE, p-side dot electrodes P1, a p-side wiring electrode P2, and a p-side pad electrode PE.

The substrate 110 serves as a supporting substrate for supporting the semiconductor layers, or may also serve as a growth substrate. The main surface of the substrate 110 is preferably embossed. The substrate 110 is made of sapphire or may be formed of another material such as SiC, ZnO, Si, or GaN.

The n-type semiconductor layer 120, the light-emitting layer 130, and the p-type semiconductor layer 140 are Group III nitride semiconductor layers formed on the substrate 110. The n-type semiconductor layer 120 includes an n-type contact layer, an n-side electrostatic breakdown-preventing layer, and an n-side superlattice layer. The n-type semiconductor layer 120 may include an undoped-GaN layer not doped with a donner or a similar layer. The p-type semiconductor layer 140 includes a p-side cladding layer and a p-type contact layer. The p-type semiconductor layer 140 may include an undoped-GaN layer not doped with an acceptor or a similar layer. The n-type semiconductor layer 120 or the p-type semiconductor layer 140 may have any layer structure differing from the above configurations.

The current-blocking layer CB1 is a layer for preventing current flow directly under the electrode and for diffusing current in the light-emitting plane. The current-blocking layer CB1 is formed on the p-type semiconductor layer 140. The current-blocking layer CB1 is formed between the p-type semiconductor layer 140 and the transparent conductive oxide film TE1. The current-blocking layer CB1 is made of a material such as MgF or SiO₂.

The transparent conductive oxide film TE1 is formed on the p-type semiconductor layer 140 and the current-blocking layer CB1. The transparent conductive oxide film TE1 serves as a transparent electrode. Example of the material of the transparent conductive oxide film TE1 include ITO, IZO, ICO, ZnO, TiO₂, NbTiO₂, TaTiO₂, and SnO₂. Alternatively, the transparent conductive oxide film TE1 may be formed of other transparent oxides.

The dielectric film F1 serves as a first dielectric film. The dielectric film F1 covers the Group III nitride semiconductor layers and at least a part of the transparent conductive oxide film TE1. Also, the dielectric film F1 covers the n-side wiring electrode N2 and the p-side wiring electrode P2. The dielectric film F1 is formed of, for example, any of Al₂O₃, SiN, SiON, Y₂O₃, and HfO₂.

The reflective film RN1 is a film for preventing radiation of the light emitted from the light-emitting layer 130 to the n-side wiring electrode N2 or other members. The reflective film RP1 is a film for preventing radiation of the light emitted from the light-emitting layer 130 to the p-side wiring electrode P2 or other members. The reflective film RN1 is formed on the n-type semiconductor layer 120, while the reflective film RP1 is disposed on the transparent conductive oxide film TE1. The dielectric film FN1 covers the reflective film RN1, and the dielectric film FP1 serves as a second dielectric film which covers the reflective film RP1.

Each of the n-side dot electrodes N1 serves as an n-type contact electrode in contact with the n-type contact layer. The n-side wiring electrode N2 serves as an electrode for electrically connecting the n-side dot electrodes N1 to the n-side pad electrode NE. The n-side pad electrode NE serves as an electrode which is electrically connected to an external power source.

Each of the p-side dot electrodes P1 serves as a p-type contact electrode in contact with the p-type contact layer. The p-side wiring electrode P2 serves as an electrode for electrically connecting the p-side dot electrodes P1 to the p-side pad electrode PE. The p-side pad electrode PE serves as an electrode which is electrically connected to an external power source.

A phosphor-containing resin coating 200 is a coating formed of a resin containing a phosphor. The phosphor is, for example, a YAG-based phosphor. The phosphor-containing resin coating 200 is formed on the dielectric film F1.

The above-described other stacking configurations of semiconductor layers and electrodes are given only for the purpose of illustration. Thus, needless to say, other stacking configurations of semiconductor layers and electrodes may be employed.

### 2. Relationship Between Stacking Configuration and Refractive Indexes

### 2-1. Stacking Configuration

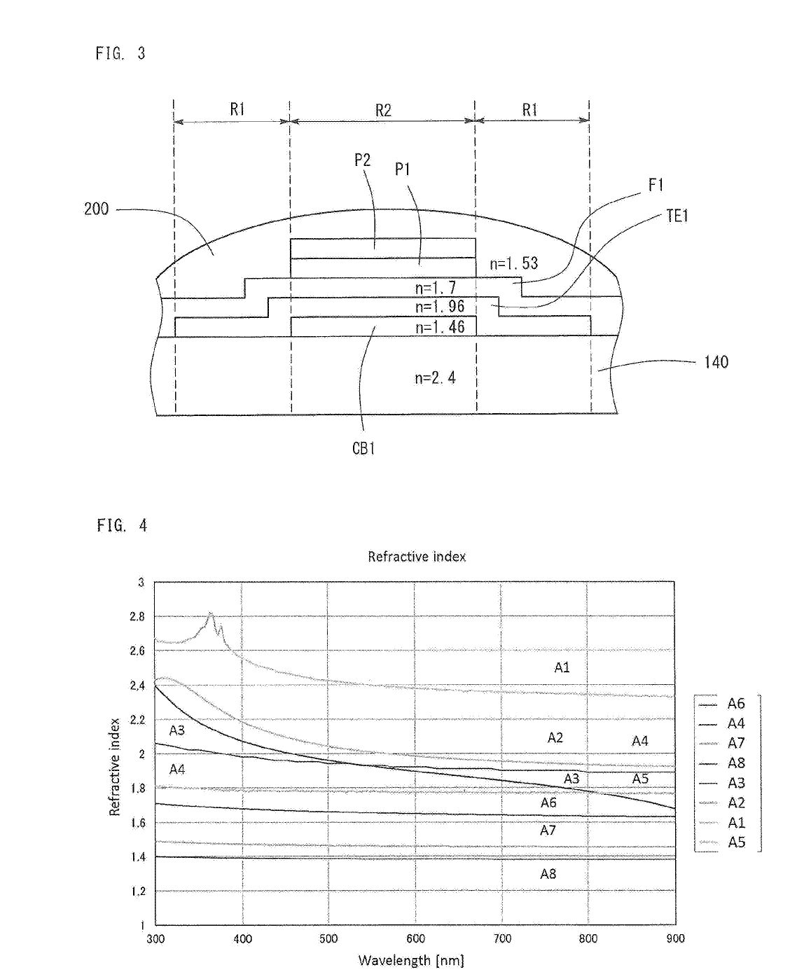

FIG. 3 is a representation showing the layer stacking configuration and the refractive indexes of respective layers. As shown in FIG. 3, the p-type semiconductor layer 140, the current-blocking layer CB1, the transparent conductive oxide film TE1, the dielectric film F1, the p-side dot electrodes P1, the p-side wiring electrode P2, and the phosphor-containing resin coating 200 are successively stacked from the semiconductor layer side.

As shown in FIG. 3, the light-emitting device 1 includes a first region R1 and a second region R2. The first region R1 includes no electrode such as the p-side dot electrodes P1, but the second region R2 includes electrodes such as the p-side dot electrodes P1. In the first region R1, the light emitted from the light-emitting layer 130 is extracted to the outside as effectively as possible. However, in the second region R2, irradiation of the electrode with the light emitted from the light-emitting layer 130 is suppressed.

The second region R2 includes the p-side dot electrodes P1 and the p-side wiring electrode P2 as well as the current-blocking layer CB1. Thus, the current-blocking layer CB1 is disposed around the projection area of the p-side dot electrodes P1 to the semiconductor layers.

### 2-2. Refractive Index

In FIG. 3, a typical refractive index of each layer is indicated. That is, the refractive index values are merely examples, and should not be limited thereto. As shown in FIG. 3, the p-type semiconductor layer 140 has a refractive index of 2.4, and the current-blocking layer CB1 has a refractive index of 1.46. The transparent conductive oxide film TE1 has a refractive index of 1.96. The dielectric film F1 has a refractive index of 1.7. The phosphor-containing resin coating 200 has a refractive index of 1.53.

The refractive index of the p-type semiconductor layer 140 is greater than that of the transparent conductive oxide film TE1. The refractive index of the transparent conductive oxide film TE1 is greater than that of the dielectric film F1. The refractive index of the dielectric film F1 is greater than that of the phosphor-containing resin coating 200. The refractive index of the current-blocking layer CB1 is smaller than that of the phosphor-containing resin coating 200.

The refractive index of the current-blocking layer CB1 is smaller than that of the p-type semiconductor layer 140. The refractive index of the current-blocking layer CB1 is smaller than that of the transparent conductive oxide film TE1.

Although not illustrated in FIG. 3, the dielectric film FP1 has a refractive index of, for example, 1.46. The refractive index of the dielectric film FP1 is smaller than that of the phosphor-containing resin coating 200.

The light-emitting element 100 includes the first region R1, which is not present directly under the current-blocking layer CB1, and the second region R2, which is present directly under the current-blocking layer CB1. Upon voltage application to the light-emitting element 100, current flows in the first region R1, which does not include the current-blocking layer CB1. As a result, light is emitted from the first region R1 of the light-emitting layer 130.

In the first region R1, the p-type semiconductor layer 140, the transparent conductive oxide film TE1, the dielectric film F1, and the phosphor-containing resin coating 200 are successively formed from the semiconductor layer side. The refractive index gradually decreases from the semiconductor layer side to the phosphor-containing resin coating 200. As a result, light reflection at each interface between adjacent layers is prevented in the first region R1. Thus, the light-emitting element 100 attains high light emission efficiency.

The second region R2 of the light-emitting layer 130 is not substantially involved in light emission. However, a portion of light emitted from the first region R1 of the light-emitting layer 130, which portion has an oblique element, may enter the second region R2. In the second region R2, the refractive index of the current-blocking layer CB1 is smaller than that of the transparent conductive oxide film TE1. Therefore, the light going from the current-blocking layer CB1 to the transparent conductive oxide film TE1 has a small critical angle. Thus, the light going from the current-blocking layer CB1 to the transparent conductive oxide film TE1 tends to be totally reflected, whereby the p-side dot electrodes P1 are not considerably irradiated with light in the second region R2. As a result, light absorption by the p-side dot electrodes P1 is reduced.

As described above, in the light-emitting device 1, total reflection is suppressed in paths for transmission of light, but is promoted in paths not for transmission of light. Thus, the light-emitting device 1 provides excellent light extraction efficiency.

### 2-3. Relationship Between Wavelength and Refractive Index of a Material

FIG. 4 is a graph showing wavelength-refractive index relationships of materials. In FIG. 4, the horizontal axis represents the wavelength of the incident light, and the vertical axis represents the refractive index. In FIG. 4, line A1 represents the change in refractive index of GaN; line A2 represents the change in refractive index of IZO; line A3 represents the change in refractive index of ITO; line A4 represents the change in refractive index of HfO₂; line A5 represents the change in refractive index of sapphire; line A6 represents the change in refractive index of Al₂O₃; line A7 represents the change in refractive index of SiO₂; and line A8 represents the change in refractive index of MgF₂.

ITO and IZO are materials of the transparent conductive oxide film TE1. Sapphire is a material of the substrate. HfO₂ and Al₂O₃ are materials of the dielectric film F1. SiO₂ and MgF₂ are materials of the current-blocking layer CB1.

As shown in FIG. 4, the refractive index of any material depends on the wavelength of the incident light to a certain extent. For example, the refractive index of ITO decreases as the wavelength increases. When the wavelength is 300 nm, the refractive index of ITO is 2.4, whereas when the wavelength is 900 nm, the refractive index of ITO is about 1.67.

The case where the wavelength is 500 nm will be described. The refractive index of GaN is about 2.42; the refractive index of IZO is about 2.05; the refractive index of ITO is about 1.95; the refractive index of HfO₂ is about 1.93; the refractive index of sapphire is about 1.78; the refractive index of Al₂O₃ is about 1.68; the refractive index of SiO₂ is about 1.46; and the refractive index of MgF₂ is about 1.4.

### 2-4. Spectrum

FIG. 5 is a graph showing the relationship between the wavelength of the light emitted by the light-emitting element 100 and the intensity of the light. In FIG. 5, the horizontal axis represents the wavelength of the emitted light, and the vertical axis represents the emission intensity. As shown in FIG. 5, there are a large peak at a wavelength of about 450 nm and a non-sharp peak at a wavelength of about 560 nm. As is clear from FIG. 5, the emission wavelength window of the light-emitting element 100 is 400 nm to 800 nm.

### 2-5. Simulation of Light Transmittance

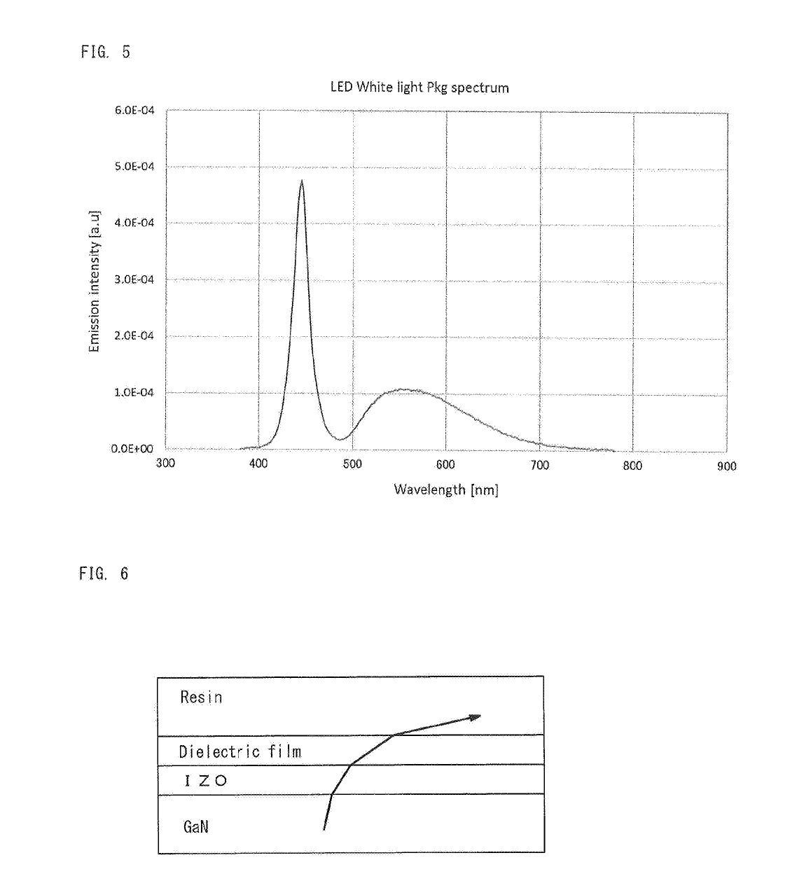

Light transmitting feature of an imagined structure illustrated in FIG. 6 was simulated. The imagined structure is a body consisting of a GaN layer, an IZO layer, a dielectric film, and a resin layer, the layer elements being stacked from the bottom. The IZO layer has a thickness of 70 nm, and the dielectric film has a thickness of 100 nm. A case of a dielectric film made of Al₂O₃ and that of a dielectric film made of SiO₂ were investigated.

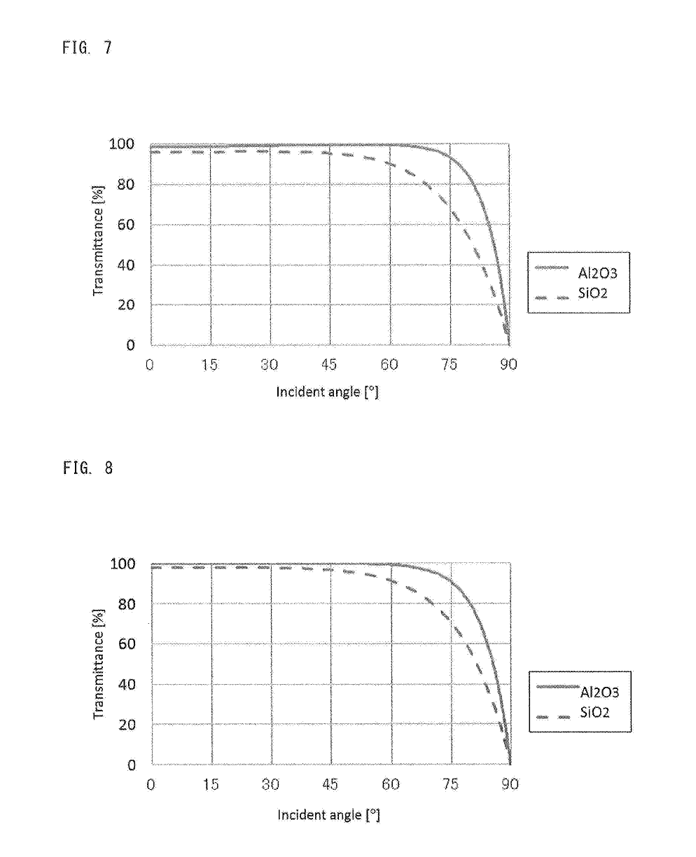

FIG. 7 is a graph showing the relationship between the incident angle and the transmittance when the light wavelength is 450 nm. In FIG. 7, the horizontal axis represents the incident angle, and the vertical axis represents the transmittance. When the dielectric film is made of Al₂O₃, the transmittance drastically decreases in an incident angle range greater than about 75°. When the dielectric film is made of Al₂O₃ and the incident angle is about 75°, the transmittance is about 90%. When the dielectric film is made of SiO₂, the transmittance drastically decreases in an incident angle range greater than about 60°. When the dielectric film is made of SiO₂ and the incident angle is about 60°, the transmittance is about 90%. As also shown in FIG. 7, the transmittance obtained when the dielectric film is made of Al₂O₃ is greater than the transmittance obtained when the dielectric film is made of SiO₂.

FIG. 8 is a graph showing the relationship between the incident angle and the transmittance when the light wavelength is 570 nm. In FIG. 8, the horizontal axis represents the incident angle, and the vertical axis represents the transmittance. When the dielectric film is made of Al₂O₃, the transmittance drastically decreases in an incident angle range greater than about 75°. When the dielectric film is made of Al₂O₃ and the incident angle is about 75°, the transmittance is about 90%. When the dielectric film is made of SiO₂, the transmittance drastically decreases in an incident angle range greater than about 60°. When the dielectric film is made of SiO₂ and the incident angle is about 60°, the transmittance is about 90%. As also shown in FIG. 8, the transmittance obtained when the dielectric film is made of Al₂O₃ is greater than the transmittance obtained when the dielectric film is made of SiO₂.

### 3. Light-Emitting Device Manufacturing Method

The production method includes a semiconductor layer formation step of forming a Group III nitride semiconductor layer on a substrate; a current-blocking layer formation step of forming a current-blocking layer on the Group III nitride semiconductor layer; a transparent conductive oxide film formation step of forming a transparent conductive oxide film on the Group III nitride semiconductor layer and the current-blocking layer; a first dielectric film formation step of covering the Group III nitride semiconductor layer and at least a part of the transparent conductive oxide film with a first dielectric film; and a phosphor-containing resin coating formation step forming a phosphor-containing resin coating on the first dielectric film.

### 3-1. Semiconductor Layer Formation Step

On the substrate 110, the n-type semiconductor layer 120, the light-emitting layer 130, and the p-type semiconductor layer 140 are formed. More specifically, on the substrate 110, semiconductor layers; an n-type contact layer, an n-side electrostatic breakdown-preventing layer, an n-side superlattice layer, a light-emitting layer, a p-side cladding layer, and a p-type contact layer are sequentially formed. The semiconductor layers in the form of crystalline layers are epitaxially formed through metal-organic chemical vapor deposition (MOCVD). The carrier gas employed in the growth of semiconductor layers is hydrogen (H₂), nitrogen (N₂), or a mixture of hydrogen and nitrogen (H₂+N₂). Ammonia gas (NH₃) is used as a nitrogen source. Trimethylgallium (Ga(CH₃)₃: (TMG)) is used as a gallium source. Trimethylindium (In(CH₃)₃: (TMI)) is used as an indium source, and trimethylaluminum (Al(CH₃)₃: (TMA)) is used as an aluminum source. Silane (SiH₄) is used as an n-type dopant gas, and biscyclopentadienylmagnesium (Mg(C₅H₅)₂) is used as a p-type dopant gas. Needless to say, gases other than the above may also be used.

### 3-2. Current-Blocking Layer Formation Step

The current-blocking layer CB1 is formed on the p-type contact layer of the p-type semiconductor layer 140. The current-blocking layer CB1 may be formed through CVD. The current-blocking layer CB1 has a film thickness of, for example, 100 nm. Patterning of the current-blocking layer CB1 at a desired position and to a desired shape may be performed through photolithography.

### 3-3. Transparent Conductive Oxide Film Formation Step

On the current-blocking layer CB1 and the p-type contact layer, the transparent conductive oxide film TE1 is then formed. In an example, an IZO film is formed through sputtering. The transparent conductive oxide film TE1 has a thickness of, for example, 70 nm. The transparent conductive oxide film TE1 is then subjected to a thermal treatment in an atmosphere at 650° C.

3-4. n-Type Semiconductor Layer Exposing Step

Subsequently, a part of the p-type semiconductor layer 140 and a part of the light-emitting layer 130 are removed by means of ICP, whereby a part of the n-type semiconductor layer 120 is exposed.

### 3-5. Dot Electrode Formation Step

Then, the n-side dot electrodes N1 and p-side dot electrodes P1 are formed. In one mode, Ni (50 nm), Au (250 nm), and Al (10 nm) are sequentially formed through a vapor deposition technique. Then, a thermal treatment is carried out at 550° C. under oxygen. The pressure at the thermal treatment is, for example, 15 Pa.

### 3-6. Reflective Film Formation Step (Second Dielectric Film Formation Step)

The dielectric film FN1 and the dielectric film FP1 are formed through CVD so as to control the thickness of each film to be 300 nm. The reflective film RN1 and the reflective film RP1 are formed though a vapor deposition technique. Thereafter, the dielectric film FN1 and the dielectric film FP1 are further formed through CVD so as to have a film thickness of 100 nm. Through the above procedure, the reflective film RP1 is covered with the dielectric film FP1. The reflective film RN1 and the reflective film RP1 are formed of, for example, A1. The reflective film RN1 and the reflective film RP1 respectively have a film thickness of, for example, 100 nm.

### 3-7. Wiring Electrode Formation Step

Then, the n-side wiring electrode N2 and the p-side wiring electrode P2 are formed. In one mode, Ti (50 nm), Au (1,500 nm), and Al (10 nm) are sequentially formed through a vapor deposition technique. Notably, the n-side pad electrode NE and the p-side pad electrode PE may be formed separately.

### 3-8. Protective Film Formation Step (First Dielectric Film Formation Step)

Then, the dielectric film F1 is formed. The semiconductor layers, a part of the transparent conductive oxide film TE1, the p-side wiring electrode P2, and the n-side wiring electrode N2 are covered with the dielectric film F1. In one mode, the dielectric film F1 is formed through CVD so as to have a film thickness of, for example, 100 nm. Alternatively, the atomic layer deposition (ALD) technique may also be employed.

### 3-9. Element Isolation Step

The product wafer is cut into a large number of light-emitting elements 100.

### 3-10. Phosphor-Containing Resin Coating Formation Step

On the light extraction face of each light-emitting element 100, the phosphor-containing resin coating 200 is provided.

### 3-11. Other Steps

The production method may further include other steps such as a wiring step for providing each pad electrode with wiring. Notably, the mentioned production steps are provided as examples. Accordingly, the aforementioned stacking configurations, numerical values, etc. are also given as examples. Needless to say, numerical values other than those given above may also be employed.

### 4. Variations

### 4-1. Wiring Electrode

The light-emitting device 1 of the first embodiment has the n-side wiring electrode N2 and the p-side wiring electrode P2. However, the technique of the present embodiment may also be applied to a light-emitting device having no n-side wiring electrode N2 or p-side wiring electrode P2.

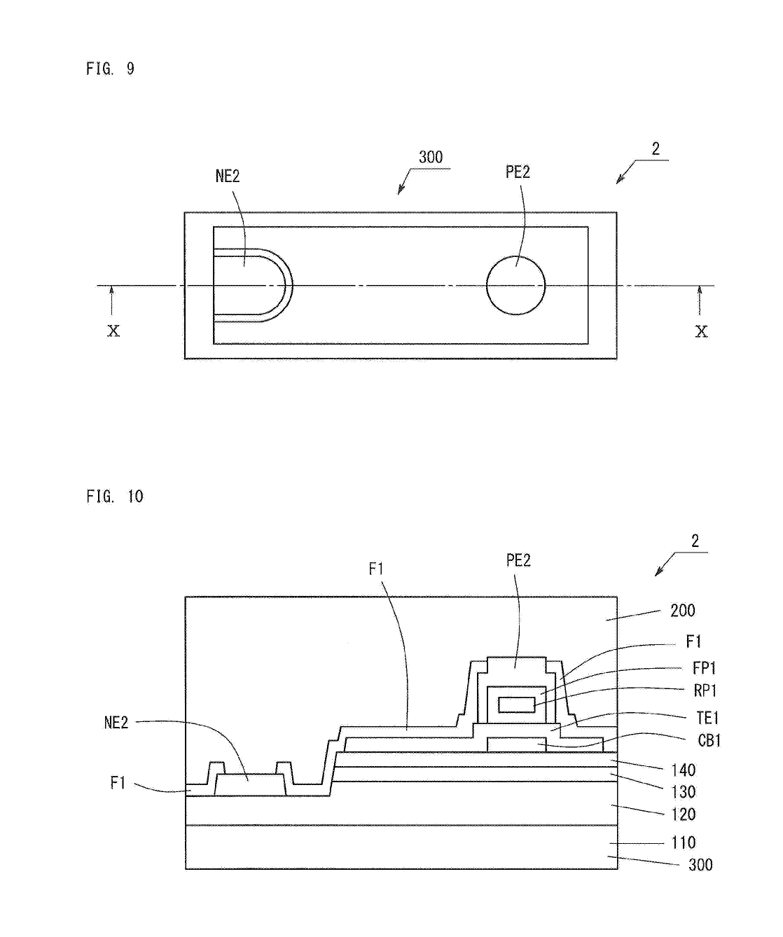

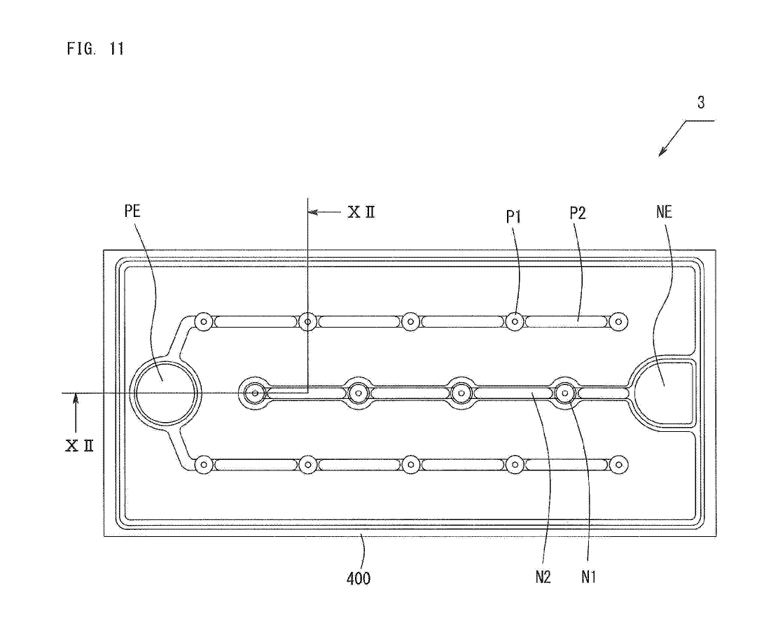

FIG. 9 is a plan view of a light-emitting device 2 having no wiring electrode. FIG. 10 is a cross-section of the light-emitting device 2 shown in FIG. 9, cut along X-X. As shown in FIGS. 9 and 10, the light-emitting device 2 has a light-emitting element 300 and a phosphor-containing resin coating 200. The light-emitting element 300 has a substrate 110, an n-type semiconductor layer 120, a light-emitting layer 130, a p-type semiconductor layer 140, a current-blocking layer CB1, a transparent conductive oxide film TE1, a dielectric film F1, a dielectric film FP1, a reflective film RP1, an n-side pad electrode NE2, and a p-side pad electrode PE2.

In the above case, in a region corresponding to the first region R1, the p-type semiconductor layer 140, the transparent conductive oxide film TE1, the dielectric film F1, and the phosphor-containing resin coating 200 are sequentially stacked from the semiconductor layer side. In a region corresponding to the second region R2, the p-type semiconductor layer 140, the current-blocking layer CB1, the transparent conductive oxide film TE1, the dielectric film FP1, the reflective film RP1, the dielectric film FP1, the A-side pad electrode PE2, and the phosphor-containing resin coating 200 are sequentially stacked from the semiconductor layer side. Thus, the light-emitting device 2 has the same refractive index profile as that of the first embodiment. That is, the technique of the first embodiment may be applied to the light-emitting device 2.

4-2. p-Type Contact Electrode and n-Type Contact Electrode

In the first embodiment, the p-type contact electrode is formed of p-side dot electrodes P1, and the n-type contact electrode is formed of n-side dot electrodes N1. No particular limitation is imposed on the contact electrodes, and a p-type contact electrode and an n-type contact electrode of another shape may also be employed.

### 5. Summary of the First Embodiment

As described above, in the light-emitting device 1 of the first embodiment, the p-type semiconductor layer 140, the current-blocking layer CB1, the transparent conductive oxide film TE1, the dielectric film F1, the p-side dot electrodes P1, the p-side wiring electrode P2, and the phosphor-containing resin coating 200 are sequentially stacked from the semiconductor layer side. The refractive index of the p-type semiconductor layer 140 is greater than that of the transparent conductive oxide film TE1; the refractive index of the transparent conductive oxide film TE1 is greater than that of the dielectric film F1; the refractive index of the dielectric film F1 is greater than that of the phosphor-containing resin coating 200; the refractive index of the current-blocking layer CB1 is smaller than that of the phosphor-containing resin coating 200. As a result, the light-emitting device 1 provides an excellent light emission intensity.

Notably, the aforementioned embodiments are given for the illustration purpose. Thus, needless to say, various modifications and variations can be made, so long as they fall within the scope of the present technique. No particular limitation is imposed on the stacking configuration of the layer structure, and any stacking configuration other than those described above may be employed. For example, the stacking configuration, the number of repetitions of layer sets, etc. may be chosen without any limitation. The film formation technique is not limited to metal-organic chemical vapor deposition (MOCVD). Other similar techniques may be employed, so long as they employ carrier gas in crystal growth. Alternatively, the semiconductor layers may be formed through another epitaxial growth technique such as liquid phase epitaxy or molecular beam epitaxy.

### Second Embodiment

Second embodiment will be described.

### 1. Light-Emitting Device

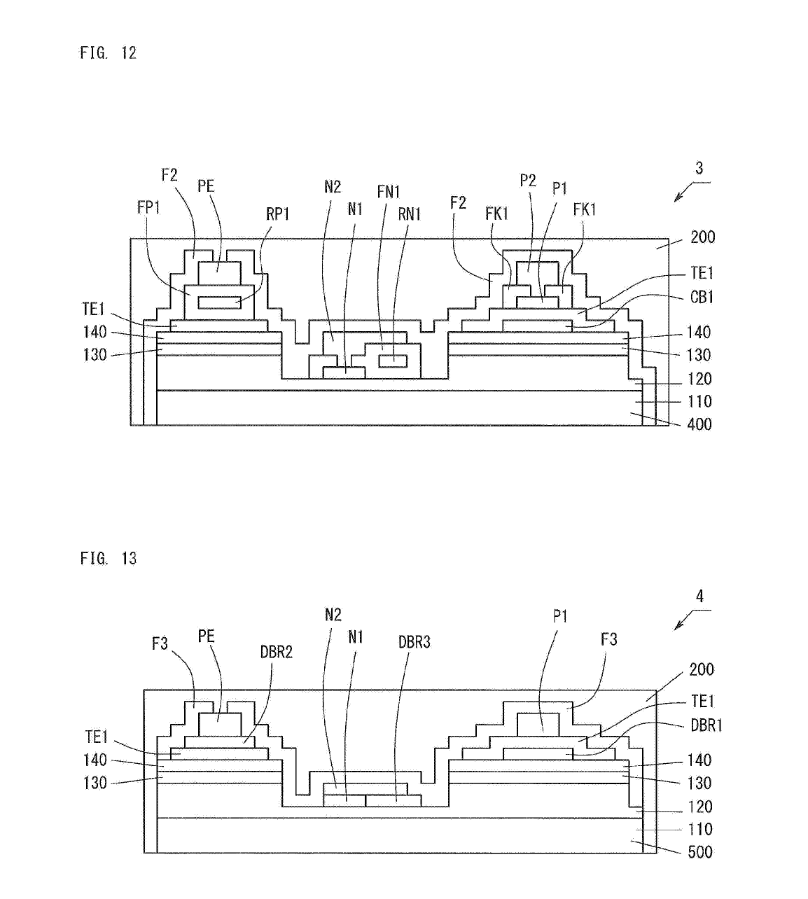

FIG. 11 is a plan view of the general structure of a light-emitting device 3 of the second embodiment, and FIG. 12 is a cross-section of the light-emitting device 3 shown in FIG. 11, cut along XII-XII. The light-emitting device 3 has a light-emitting element 400 and a phosphor-containing resin coating 200.

As shown in FIGS. 11 and 12, the light-emitting element 400 has a substrate 110, an n-type semiconductor layer 120, a light-emitting layer 130, a p-type semiconductor layer 140, a current-blocking layer CB1, a transparent conductive oxide film TE1, a dielectric film F2, a dielectric film FN1, a dielectric film FP1, a dielectric film FK1, a reflective film RN1, a reflective film RP1, n-side dot electrodes N1, an n-side wiring electrode N2, an n-side pad electrode NE, p-side dot electrodes P1, a p-side wiring electrode P2, and a p-side pad electrode PE.

### 2. Relationship Between Stacking Configuration and Refractive Index

The light-emitting element 400 of the second embodiment differs from the light-emitting element 100 of the first embodiment, in terms of dielectric film. The dielectric film F2 serves as a first dielectric film. The dielectric film F2 of the light-emitting element 400 covers the Group III nitride semiconductor layer and at least a part of the transparent conductive oxide film TE1. The dielectric film F2 covers the n-side wiring electrode N2 and the p-side wiring electrode P2. In addition, the dielectric film F2 of the light-emitting element 400 covers a side surface of the Group III nitride semiconductor layer and a side surface of the substrate 110.

The refractive index of the substrate 110 is 1.78. The refractive index of the dielectric film F2 is 1.7. The refractive index of the phosphor-containing resin coating 200 is 1.53. Thus, the refractive index of the substrate 110 is greater than that of the dielectric film F2, and the refractive index of the dielectric film F2 is greater than that of the phosphor-containing resin coating 200.

### 3. Light-Emitting Device Production Method

The method for producing the light-emitting device of the second embodiment is substantially the same as the method for producing the light-emitting device of the first embodiment. Thus, only the difference between the two production methods will be described. In the first dielectric film formation step included in the method for producing the light-emitting device of the second embodiment, the dielectric film F2 is formed on a side surface of the substrate 110, in addition to the Group III nitride semiconductor layer.

### Third Embodiment

Third embodiment will be described.

### 1. Light-Emitting Device

FIG. 13 is a cross-section of the light-emitting device 4 of the third embodiment. The light-emitting device 4 has a light-emitting element 500 and a phosphor-containing resin coating 200.

As shown in FIG. 13, the light-emitting element 500 has a substrate 110, an n-type semiconductor layer 120, a light-emitting layer 130, a p-type semiconductor layer 140, a distributed Bragg reflector DBR1, a transparent conductive oxide film TE1, a distributed Bragg reflector DBR2, a distributed Bragg reflector DBR3, a dielectric film F3, n-side dot electrodes N1, an n-side wiring electrode N2, an n-side pad electrode NE, p-side dot electrodes P1, a p-side wiring electrode P2, and a p-side pad electrode PE.

The distributed Bragg reflectors DBR1, DBR2, and DBR3 serve as films each selectively reflecting light having a wavelength λ. The dielectric film F3 serves as an anti-reflector (AR).

Thus, when the distributed Bragg reflectors DBR1, DBR2, and DBR3, and an anti-reflector are employed, the same effects as obtained in the first embodiment can also be attained.

What is claimed is:

1. A light-emitting device, comprising:
a substrate,
a Group III nitride semiconductor layer on the substrate,
a current-blocking layer on the Group III nitride semiconductor layer,
a transparent conductive oxide film on the Group III nitride semiconductor layer and the current-blocking layer,
a first dielectric film covering at least a part of the Group III nitride semiconductor layer and at least a part of the transparent conductive oxide film, and
a phosphor-containing resin coating on the first dielectric film, wherein
the Group III nitride semiconductor layer has a refractive index greater than that of the transparent conductive oxide film;
the transparent conductive oxide film has a refractive index greater than that of the first dielectric film;
the first dielectric film has a refractive index greater than that of the phosphor-containing resin coating; and
the current-blocking layer has a refractive index smaller than that of the phosphor-containing resin coating.

2. The light-emitting device according to claim 1, wherein the light-emitting device comprises a reflective film on the transparent conductive oxide film, and a second dielectric film covering the reflective film, and the second dielectric film has a refractive index smaller than that of the phosphor-containing resin coating.

3. The light-emitting device according to claim 1, wherein the first dielectric film covers a side surface of the substrate, and the substrate has a refractive index greater than that of the first dielectric film.

4. The light-emitting device according to claim 1, which has an emission wavelength of 400 nm to 800 nm.

5. The light-emitting device according to claim 1, wherein the transparent conductive oxide film is formed of IZO.

6. A method for producing a light-emitting device, the method comprising:
forming a Group III nitride semiconductor layer on a substrate,
forming a current-blocking layer on the Group III nitride semiconductor layer,
forming a transparent conductive oxide film on the Group III nitride semiconductor layer and the current-blocking layer,
covering at least a part of the Group III nitride semiconductor layer and at least a part of the transparent conductive oxide film with a first dielectric film, and
forming a phosphor-containing resin coating on the first dielectric film, wherein
the Group III nitride semiconductor layer has a refractive index greater than that of the transparent conductive oxide film; the transparent conductive oxide film has a refractive index greater than that of the first dielectric film; the first dielectric film has a refractive index greater than that of the phosphor-containing resin coating; and the current-blocking layer has a refractive index smaller than that of the phosphor-containing resin coating.

7. The light-emitting device production method according to claim 6, wherein the method further comprises forming a reflective film on the transparent conductive oxide film, and covering the reflective film with a second dielectric film, and the second dielectric film has a refractive index smaller than that of the phosphor-containing resin coating.

8. The light-emitting device production method according to claim 6, wherein, in the first dielectric film formation, the first dielectric film is formed on a side surface of the substrate, and the substrate has a refractive index greater than that of the first dielectric film.
